(19) United States
(12) Patent Application Publication
(10) Pub. No.: US 2017/0166442 A1
(43) Pub. Date: Jun. 15, 2017

(54) SYSTEM AND METHOD FOR PROVIDING HERMETICALLY SEALED PACKAGES WITH CONSISTENT VACUUM CAVITY

(71) Applicant: INTEGRATED DEVICE TECHNOLOGY, INC., San Jose, CA (US)

(72) Inventors: Srikanth Kulkarni, Freemont, CA (US); Viresh P. Patel, Austin, TX (US)

(73) Assignee: Integrated Device Technology, Inc.

(21) Appl. No.: 14/967,007

(22) Filed: Dec. 11, 2015

(51) Int. Cl. B81C 1/00; H01L 21/52

(52) U.S. Cl. CPC B81C 1/00269; H01L 21/52; B81C 2203/019

(57) ABSTRACT

A method of forming a plurality of sealed packages comprises providing a base including a base surface; providing a lid including a lid surface; positioning a plurality of spaced apart seal members along the base surface, the seal members being formed from a seal material including a fusible metal alloy; positioning the lid on the base with a plurality of spaced apart spacers positioned and extending between the base surface and the lid surface, the spacers maintaining the lid surface spaced apart from the seal members by a fluid gap, the spacers being made from a spacer material including a fusible metal alloy; creating a controlled environment around the base and the lid; and heating to melt the spacers and the seal material so that the seal members form a plurality of seal rings between the base surface and the lid surface.

### BACKGROUND

A microelectronic package typically includes a first package member, e.g., a package body, that defines a package cavity, and a second package member, e.g., a lid, that is secured to the first package member. Additionally, a device, e.g., a MEMS package, an integrated circuit or another suitable device, is often secured within the package, with desired electrical connections being made through the package body. In various applications, it is desired to create a hermetic seal ring around the package cavity. To create such a hermetic seal ring, a solder, i.e. a fusible metal alloy, or another appropriate braze material is commonly used. The solder/braze material can be provided either in preform or a plated form. The solder is typically applied to one of the surfaces—either the cavity or the lid, and the other surface is finished with a wettable metal. The lid is then placed over the cavity with the solder/braze and reflowed. The solder/braze will wet the entire length of the seal ring to create a hermetic seal.

### SUMMARY

The present invention is directed toward a method of forming a plurality of sealed packages. In various embodiments, the method comprises (i) providing a base including a base surface; (ii) providing a lid including a lid surface; (iii) positioning a plurality of seal members along the base surface, the plurality of seal members being spaced apart from one another, the seal members being formed from a seal material including a fusible metal alloy; (iv) positioning the lid on the base with a plurality of spaced apart spacers positioned and extending between the base surface and the lid surface, the spacers maintaining the lid surface spaced apart from the seal members by a fluid gap, the spacers being made from a spacer material including a fusible metal alloy; (v) creating a controlled environment around the base and the lid; and (vi) heating to melt the spacers and the seal material so that the seal members form a plurality of seal rings between the base surface and the lid surface.

With this design, as provided herein, the method is able to form a plurality of hermetically sealed packages with a substantially consistent vacuum pressure level therein in large batch arrays that improve throughput and decrease overall costs.

In some embodiments, positioning the plurality of seal members includes the seal members having a seal melting point, and positioning the lid includes the spacers having a spacer melting point. Additionally, in such embodiments, heating can include heating the base and the lid to at least the seal melting point and the spacer melting point to melt the spacers and the seal material so that the seal members form a plurality of seal rings between the base surface and the lid surface.

Additionally, providing the base can include the base having a base melting point, and providing the lid can include the lid having a lid melting point, wherein the base melting point and the lid melting point are both greater than the seal melting point and the spacer melting point. Further, in such embodiments, heating includes heating the base and the lid to below the base melting point and the lid melting point.

In certain embodiments, the seal members have a seal thickness that extends away from the base surface, and the spacers have a spacer thickness that extends away from the base surface. In such embodiments, the spacer thickness is greater than the seal thickness.

Further, in some embodiments, providing the base includes the base defining a plurality of spaced apart package cavities, each package cavity including a cavity opening that is formed at the base surface. In such embodiments, heating can include the seal members forming a plurality of seal rings between the base surface and the lid surface, with each seal ring encircling one of the cavity openings. Additionally, in some such embodiments, the method further comprises positioning a plurality of devices between the base surface and the lid surface prior to positioning the lid on the base such that one of the plurality of devices is positioned within each package cavity.

Additionally, creating can include positioning the base and the lid within a chamber and adjusting a chamber pressure within the chamber. The chamber pressure can be adjusted in any suitable manner. For example, the chamber pressure can be adjusted by evacuating gases from within the chamber. In some such embodiments, heating can include forming a sealed package within each seal ring between the base and the lid. Each sealed package can have a package pressure that is substantially identical to the chamber pressure. Moreover, each sealed package can have a substantially identical package pressure.

### BRIEF DESCRIPTION OF THE DRAWINGS

The novel features of this invention, as well as the invention itself, both as to its structure and its operation, will be best understood from the accompanying drawings, taken in conjunction with the accompanying description, in which similar reference characters refer to similar parts, and in which:

FIG. 1A is a perspective view illustration of an embodiment of a package assembly having features of the present invention;

FIG. 1B is an exploded perspective view illustration of the package assembly of FIG. 1A;

FIG. 1C is a simplified top view illustration of the package assembly of FIG. 1A;

FIG. 1D is a simplified cutaway view of the package assembly taken on line D-D in FIG. 1C;

FIG. 1E is a simplified sectional side view of the package assembly of FIG. 1A after heating of the package assembly;

FIG. 2A is a simplified top view illustration of a portion of another embodiment of a package assembly having features of the present invention;

FIG. 2B is a simplified cutaway view of the package assembly taken on line B-B in FIG. 2A; and

FIG. 3 is a flowchart that illustrates an embodiment of a method of forming a plurality of sealed packages with the package assembly of FIG. 1A.

### DESCRIPTION

Embodiments of the present invention are described herein in the context of a package assembly and method of forming a plurality of sealed packages. Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

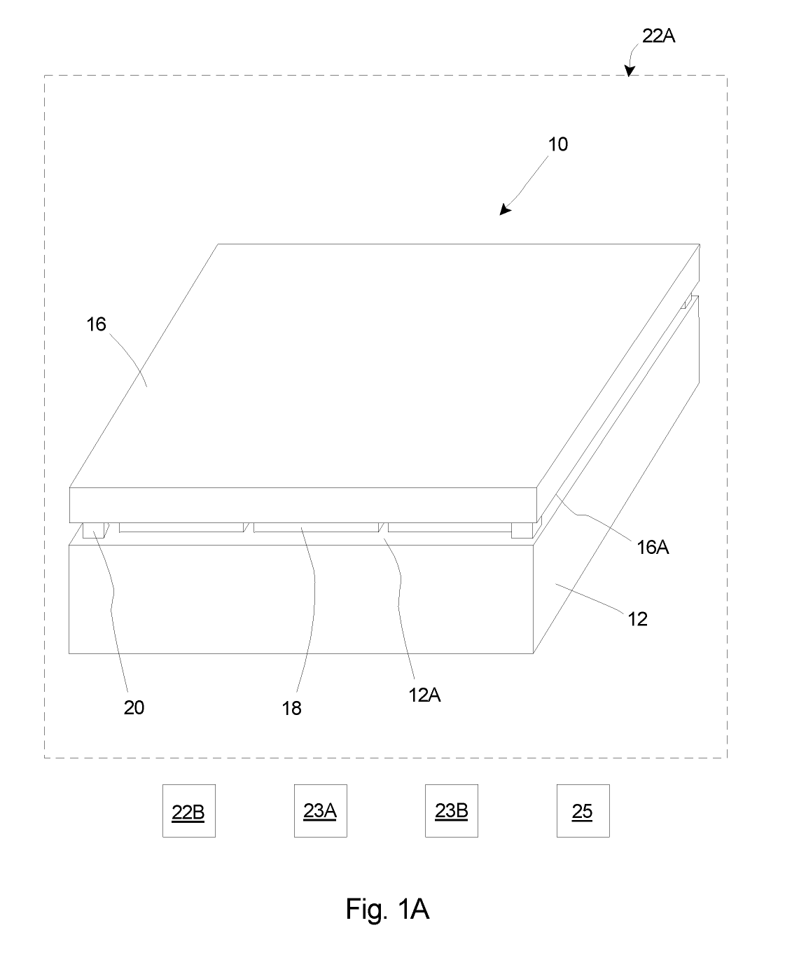

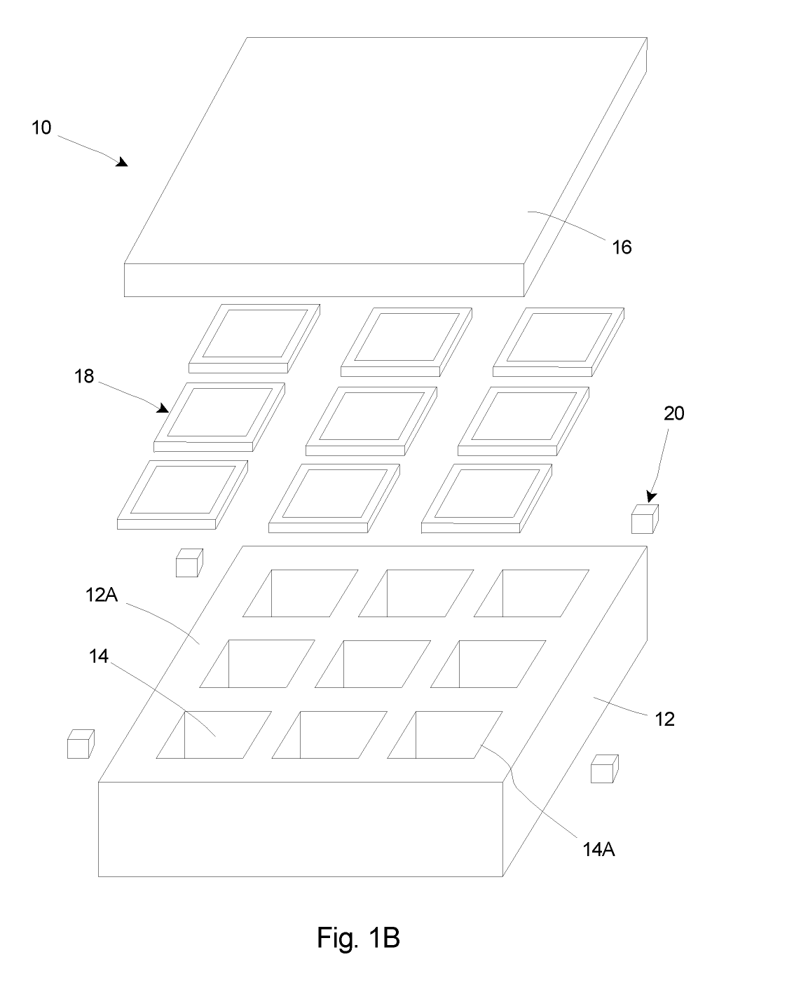

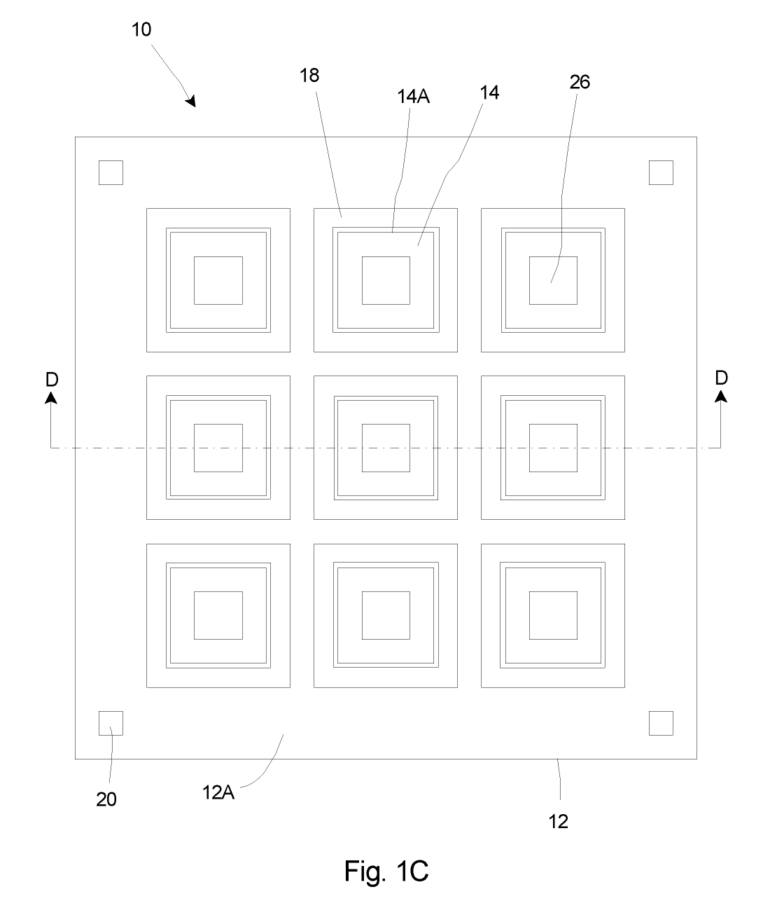

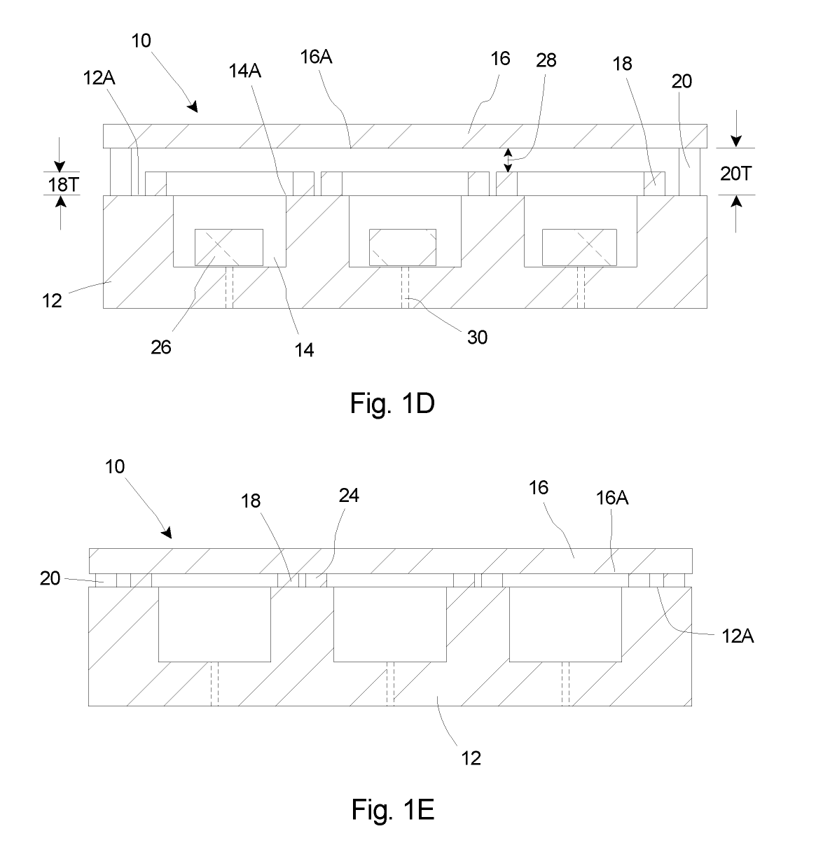

FIG. 1A is a perspective view illustration of an embodiment of a package assembly 10 having features of the present invention. In particular, FIG. 1A illustrates the package assembly 10 prior to certain steps being taken during the process of forming a plurality of sealed packages 11 (illustrated in FIG. 1E).

The design of the package assembly 10 can be varied. In this embodiment, the package assembly 10 includes a first assembly member 12, e.g., a package body or package base (also sometimes referred to herein simply as a “body” or “base”), which can define a plurality of package cavities 14 (illustrated, for example, in FIG. 1B); a second assembly member 16, e.g., a package lid (sometimes referred to herein simply as a “lid”); a plurality of seal members 18; and a plurality of spacers 20. Additionally and/or alternatively, in certain embodiments, the second assembly member 16 can define some or all of the plurality of package cavities 14. Still alternatively, the package assembly 10 can include more components or fewer components than those specifically illustrated herein.

As an overview, the package assembly 10 is uniquely designed such that the plurality of spacers 20 maintain the second assembly member 16 spaced apart from the first assembly member 12 and the plurality of seal members 18 prior to the sealing of the package cavities 14. Additionally, in such condition, the package assembly 10 can be subjected to a controlled environment, e.g., within an environmental chamber 22A (illustrated in dashed lines in FIG. 1A, and also referred to herein simply as a “chamber”) such as a vacuum chamber, to create a desired level of pressure within each of the package cavities 14. Subsequently, the seal members 18 and the spacers 20 can be heated to their melting point so that the seal members 18 form a plurality of seal rings 24 (illustrated in FIG. 1E), with each seal ring 24 encircling a cavity opening 14A (illustrated, for example, in FIG. 1B) of one of the package cavities 14. Thus, the package assembly 10 can provide the plurality of sealed packages 11, with the first assembly member 12 being sealed to the second assembly member 16, and with a substantially consistent level of pressure, e.g., vacuum, being formed within each of the package cavities 14, i.e. within each of the sealed packages 11.

Additionally, it should be appreciated that one or more devices 26 (illustrated in FIG. 1C), e.g., a MEMS package, an integrated circuit, or another suitable device, can be secured within each of the package cavities 14.

Moreover, the package assembly 10 and method described herein enable the generation of much larger array sizes of hermetically sealed packages in the assembly batch process. This can be especially beneficial when the level of pressure in the hermetically sealed package cavities is critical to the performance of the packaged devices. For example, the present method can be used to generate array sizes of eight thousand, ten thousand or more hermetically sealed packages 11 in a single batch. With this design, the method of forming a plurality of sealed packages 11 can be performed in a much more efficient and cost-effective manner, as it becomes much simpler with the innovations described herein to provide a consistent level of pressure within each of the sealed packages 11. Additionally, the ability to increase the package array size in the batch directly increases the throughput of the process. Further, the ability to tightly control the vacuum levels in the package cavities 14 will increase the consistency of the package operation.

The size and design of the first assembly member 12, e.g., the body or base, can be varied to suit the requirements of the package assembly 10, and will depend on the number of sealed packages 11 to be formed within a single batch. As illustrated in this embodiment, the first assembly member 12 can be substantially rectangular box-shaped, with the plurality of package cavities 14 being formed therein. Alternatively, the first assembly member 12 can be formed in another suitable shape.

Additionally, as shown in FIG. 1A, the first assembly member 12 includes a first member surface 12A, e.g., a base surface, that faces toward the second assembly member 16.

The first assembly member 12 can be formed from any suitable materials. In particular, the first assembly member 12 can be formed of materials that provide a suitable rigidity. Additionally, in various embodiments, the base 12 can have a base melting point that is greater than the melting point of the seal members 18 and the spacers 20. For example, in some such embodiments, the base 12 can have a base melting point that is at least approximately ten degrees, fifteen degrees, twenty degrees, twenty-five degrees or thirty degrees Celsius greater than that of the melting point of the seal members 18 and the spacers 20. Alternatively, the base melting point can be more than thirty degrees or less than ten degrees Celsius greater than the melting point of the seal members 18 and the spacers 20.

The second assembly member 16, e.g., the lid, can be sized and shaped in accordance with the size and shape of the first assembly member 12. Stated in another manner, the lid 16 can have the same approximate cross-sectional shape as the outer shape of the base 12. For example, as shown in FIG. 1A, the lid 16 can be substantially rectangular plate-shaped. Alternatively, the second assembly member 16 can be formed in another suitable shape.

Additionally, as illustrated, the second assembly member 16 can have a second member surface 16A, e.g., a lid surface, that faces toward the first assembly member 12.

The second assembly member 16 can be formed from any suitable materials. In particular, the second assembly member 16 can be formed of materials that provide a suitable rigidity. Additionally, in various embodiments, the lid 16 can have a lid melting point that is greater than the melting point of the seal members 18 and the spacers 20. For example, in some such embodiments, the lid 12 can have a lid melting point that is at least approximately ten degrees, fifteen degrees, twenty degrees, twenty-five degrees or thirty degrees Celsius greater than that of the melting point of the seal members 18 and the spacers 20. Alternatively, the lid melting point can be more than thirty degrees or less than ten degrees Celsius greater than the melting point of the seal members 18 and the spacers 20.

As noted above, the seal members 18 are positioned to, when heated to an appropriate temperature, form the plurality of seal rings 24 that can encircle each of the plurality of cavity openings 14A. More specifically, the seal members 18 can be positioned on the base surface 12A substantially about each of the cavity openings 14A.

The seal members 18 can be formed from any suitable material. For example, in various embodiments, the seal members 18 can be comprised of a pre-flowed solder material, i.e. a fusible metal alloy, or other suitable braze material. Additionally, the seal members 18 can have a seal melting point that is lower than the base melting point and the lid melting point of the base 12 and the lid 16, respectively.

The plurality of spacers 20 are positioned and extend between the base surface 12A of the base 12 and the lid surface 16A the lid 16 to maintain the lid 16 spaced apart from the base 12. Additionally, as shown more clearly in FIG. 1C, the spacers 20 are sized so as to maintain the lid surface 16A spaced apart from the plurality of seal members 18 during initial preparation of the plurality of sealed packages 11.

The spacers 20 can be formed from any suitable material. For example, in various embodiments, the spacers 20 are formed from material substantially similar, if not identical, to the material used to form the seal members 18. More specifically, the spacers 20 can be comprised of a pre-flowed solder material, i.e. a fusible metal alloy, or other suitable braze material. Additionally, the spacers 20 can have a spacer melting point that is lower than the base melting point and the lid melting point of the base 12 and the lid 16, respectively.

As noted above, the environmental chamber 22A is configured to provide a controlled environment about the package assembly 10. In particular, the environmental chamber 22A can be any appropriate type of environmental chamber, such as a vacuum reflow chamber. As provided herein, the spacers 20 are sized relative to the seal members 18 such that a fluid gap 28 (illustrated in FIG. 1D) is maintained between the lid 16 and the seal members 18 prior to the sealing of the sealed packages 11. As the atmosphere in the environmental chamber 22A is adjusted, e.g., evacuated, the gases inside the package cavities 14 are also adjusted, e.g., evacuated, easily because of the extra clearance of the fluid gap 28 created by the spacers 20. For example, in certain embodiments, an environmental control source 22B (illustrated as a box) can be provided to control the environmental pressure within the environmental chamber 22A and thus within the sealed packages 11.

After the required level of pressure is reached inside the chamber 22A, the temperature within the chamber 22A can be ramped to the seal melting point and the spacer melting point, which can be substantially identical. In particular, in various embodiments, a temperature control source 23A (illustrated as a box) and/or a heat source 23B (illustrated as a box) can be utilized to control the temperature within the chamber 22A. Thus, the seal members 18 and the spacers 20 will start to collapse at the same time, with the seal members 18 forming the desired seal rings 24 about each of the cavity openings 14A. It should be appreciated that in raising the temperature to melt the seal members 18 and the spacers 20, it is important that the temperature still be maintained below the base melting point and the lid melting point.

Also shown in FIG. 1A is a control system 25 (illustrated as a box) that can be utilized to control various features and aspects employed in the present method. More particularly, the control system 25 can include one or more processors that can be utilized to control the environmental control source 22B, the temperature control source 23A and the heat source 23B.

FIG. 1B is an exploded perspective view illustration of the package assembly 10 of FIG. 1A. In particular, FIG. 1B more clearly illustrates certain features and aspects of the various components of the package assembly 10.

In this embodiment, the first assembly member 12 is sized to define nine package cavities 14 arranged in a three-by-three array. Alternatively, the first assembly member 12 can be sized to define greater than nine or fewer than nine package cavities 14 that can be arranged in any suitable array.

As noted above, in certain embodiments, the second assembly member 16 can define a plurality of cavities in addition to or in lieu of the package cavities 14 that are defined by the first assembly member 12. In this embodiment, however, the second assembly member 16 is shaped as a simple rectangular plate that is sized and shaped to cover and enclose the package cavities 14 during the process of forming the plurality of sealed packages 11 (illustrated in FIG. 1E).

As shown in FIG. 1B, each of the seal members 18 can be substantially rectangular ring-shaped. Additionally, the seal members 18 can be sized to fit about each of the cavity openings 14A. For example, in this embodiment, the package assembly 10 includes nine seal members 18, with one seal member 18 being sized and shaped to be positioned along the base surface 12A about each of the cavity openings 14A. Alternatively, the seal members 18 can have a different shape. Still alternatively, the seal members 18 can comprise multiple spaced apart seal members 18 to be positioned about each of the cavity openings 14A, provided the seal members are large enough and close enough together so as to enable the formation of an appropriate seal ring 24 (illustrated in FIG. 1E) that completely encircles each cavity opening 14A after the package assembly 10 has been heated as desired.

Additionally, as illustrated, each of the spacers 20 can be substantially rectangular cube-shaped. In this embodiment, the package assembly 10 can include four spacers 20, with one spacer 20 to be positioned on the base surface 12A near each corner of the base 12. Alternatively, the package assembly 10 can be designed with greater than four or fewer than four spacers 20, the spacers 20 can be positioned in a different manner than described above, and/or the spacers 20 can have a different shape, such as cylindrical.

FIG. 1C is a simplified top view illustration of the package assembly 10 of FIG. 1A. In FIG. 1C the second assembly member 16 is transparent, and thus essentially not visible, so that the details of the first assembly member 12, the package cavities 14, the plurality of seal members 18, and the plurality of spacers 20 are more clearly illustrated. Additionally, FIG. 1C further illustrates a device 26, e.g., a MEMS package, an integrated circuit or another suitable device, being positioned and/or secured within each of the package cavities 14.

As clearly illustrated in FIG. 1C, one seal member 18 is positioned along the base surface 12A of the first assembly member 12 about each of the cavity openings 14A. Additionally, one spacer 20 is positioned along the base surface 12A near each corner of the base 12. It should be appreciated that, as noted above, the number of seal members 18 and spacers 20 can be varied to suit the specific requirements of the package assembly 10.

FIG. 1D is a simplified cutaway view of the package assembly 10 taken on line D-D in FIG. 1C. More specifically, FIG. 1D more clearly illustrates the size and positioning of the seal members 18 and the spacers 20 prior to heating of the package assembly 10 to form the seal rings 24 (illustrated in FIG. 1E) from the seal members 18.

As described above, each of the seal members 18 is sized and shaped to be positioned along the base surface 12A of the first assembly member 12 about one of the cavity openings 14A. Additionally, as shown, the seal members 18 have a seal member thickness 18T, which is the distance that the seal member 18 extends away from the base surface 12A in its preflow form. In certain embodiments, the seal member thickness 18T can be between approximately two and twenty microns. Alternatively, the seal member thickness 18T can be greater than approximately twenty microns or less than approximately two microns.

Additionally, as described above, each of the spacers 20 is sized so as to maintain the lid surface 16A of the second assembly member 16 spaced apart from the base surface 12A and the seal members 18 when the seal members 18 and the spacers are in their preflow form. More particularly, each of the spacers 20 has a spacer thickness 20T, which is the distance that the spacer 20 extends away from the base surface 12A, that is greater than the seal member thickness 18T. In certain embodiments, the spacer thickness 20T can be between approximately three microns and forty microns. Alternatively, the spacer thickness 20T can be greater than approximately forty microns or less than approximately three microns.

Moreover, in certain embodiments, the spacer thickness 20T can between approximately ten percent and one hundred percent thicker than the seal member thickness 18T. For example, in certain non-exclusive alternative embodiments, the spacer thickness 20T can be approximately one percent, five percent, ten percent, twenty percent, thirty percent, forty percent, fifty percent, sixty percent, seventy percent, eighty percent, ninety percent, or one hundred percent thicker than the seal member thickness 18T.

It should be appreciated that relative and/or absolute difference in thicknesses 18T, 20T between the seal members 18 and the spacers 20, respectively, must be sufficient that the atmosphere that is being evacuated from the environmental chamber 22A (illustrated in FIG. 1A) is also easily evacuated from within each of the package cavities 14. For example, in certain non-exclusive embodiments, a fluid gap 28 that exists between the lid surface 16A and the seal members 18 (when in preflow form) can be between approximately one micron and twenty microns. In certain embodiments, the fluid gap 28 is equal to the difference between the spacer thickness 20T and the seal thickness 18T when in preflow form. Alternatively, the fluid gap 28 can be greater than approximately twenty microns or less than approximately one micron.

Further, as illustrated in FIG. 1D, an electrical connector 30 or via can be formed within and/or adjacent to each cavity 14, e.g., at a base of the cavity 14, to provide any desired or necessary electrical connection between the device 26 and a member, e.g., a printed circuit board, that is external to the package assembly 10. In some embodiments, at least a portion of the electrical connector 30 can be sealed substantially within the first assembly member 12 so as to not adversely impact the environment within the sealed package 11 (illustrated in FIG. 1E).

FIG. 1E is a simplified sectional side view of the package assembly 10 of FIG. 1A. In particular, FIG. 1E illustrates the same essential view of the package assembly 10 that was illustrated in FIG. 1D, but after the desired heating of the package assembly 10 to melt the seal members 18 and the spacers 20.

As shown, in FIG. 1E, after such heating of the package assembly 10, the seal members 18 and the spacers 20 have become melted and are now of substantially the same thickness. Stated in another manner, after such heating, the fluid gap 28 (illustrated in FIG. 1D) no longer exists between the lid surface 16A of the second assembly member 16 and the seal members 18.

Moreover, as illustrated, the seal members 18 have melted so as to form the seal rings 24 that encircle each of the cavity openings 14A. The cavities 14 have now thus been hermetically sealed between the lid surface 16A and the base surface 12A of the first assembly member 12.

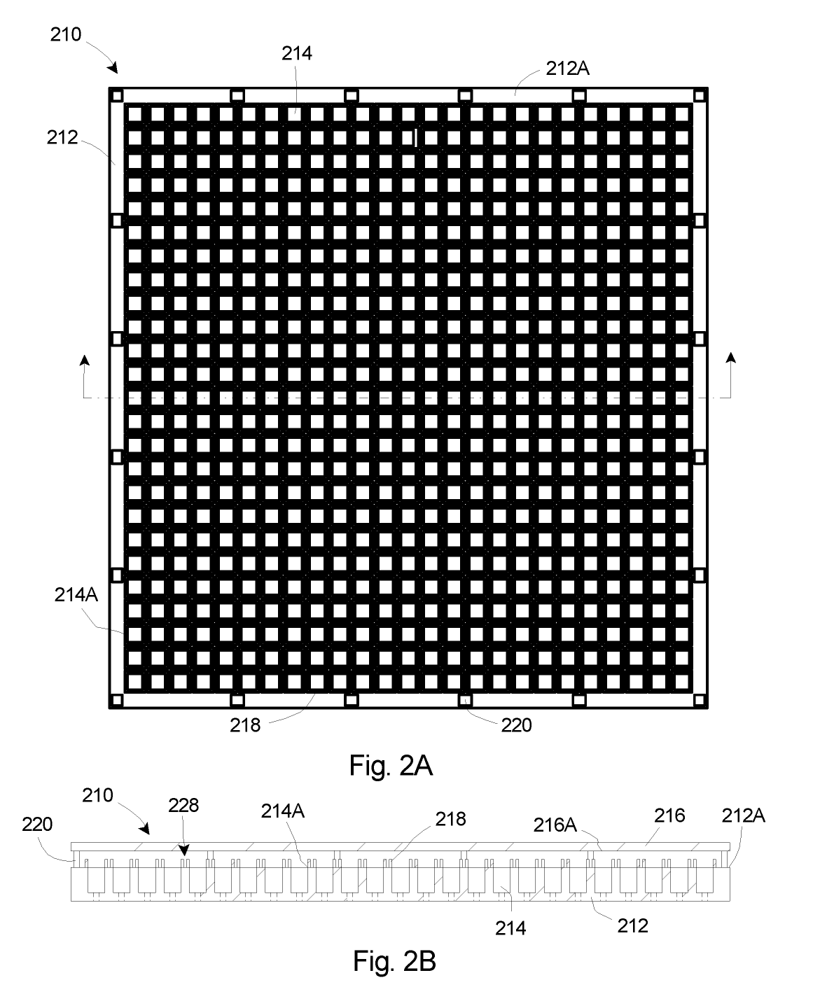

FIG. 2A is a simplified top view illustration of a portion of another embodiment of a package assembly 210 having features of the present invention. The package assembly 210 is substantially similar to the package assembly 10 illustrated and described above in relation to FIGS. 1A-1E, with the exception of the size of the package assembly 210 and the number of individual cavities 214 (and ultimately sealed packages) that are being formed in this single array. In particular, the package assembly 210 again includes a first package member 212, a second package member 216 (shown as transparent or essentially not visible in FIG. 2A for purposes of clarity), a plurality of seal members 218, and a plurality of spacers 220 that are substantially in design and function to those components illustrated and described above.

However, as noted, the number of cavities 214 is different than in the previous embodiment. More specifically, as shown in FIG. 2A, the first assembly member 212 is sized to define six hundred twenty-five individual cavities 214 that are arranged in a twenty-five-by-twenty-five array. Thus, there is also a corresponding increase in the number of seal members 218 such that one of the seal members 218 can be positioned to encircle each cavity opening 214A

Additionally, with the increased size of the assembly members 212, 216, there is a corresponding increase in the number of spacers 220 that are used to maintain the fluid gap 228 (illustrated in FIG. 2B) between the lid surface 216A (illustrated in FIG. 2A) and the seal members 218 when the seal members 218 are in preflow form. As shown, the package assembly 210 includes twenty spacers 220 that are substantially evenly spaced about a perimeter of the base surface 212A. Alternatively, the package assembly 210 can include greater than twenty or fewer than twenty spacers 220, and/or the spacers 220 can be positioned in another manner, such as throughout the array.

FIG. 2B is a simplified cutaway view of the package assembly 210 taken on line B-B in FIG. 2A. As shown, the seal members 218 and the spacers 220 are again illustrated as being positioned along the base surface 212A of the first assembly member 212, with the seal members 218 being positioned substantially about the cavity openings 214A of the cavities 214. Additionally, as illustrated, the spacers 220 are again functioning to maintain the lid surface 216A of the second assembly member 216 spaced apart the fluid gap 228 from the seal members 218.

As above, in this condition, the seal members 218 and the spacers 220 are in preflow form. Additionally, it should be appreciated that the cavities 214 can be effectively evacuated within the environmental chamber 22A (illustrated in FIG. 1A). Heat can then be added to melt the seal members 218 and the spacers 220 to form the desired hermetically sealed packages (not shown in FIG. 2B) having a consistent vacuum level therein.

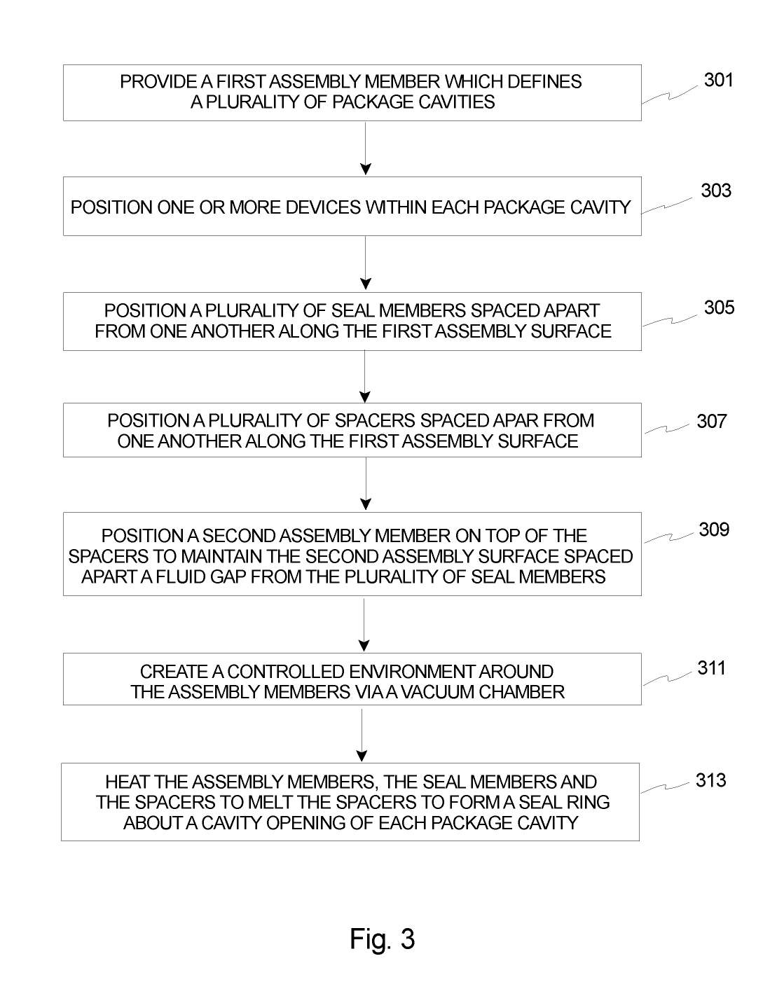

FIG. 3 is a flowchart that illustrates an embodiment of a method of forming a plurality of sealed packages within the package assembly of FIG. 1A.

It should be appreciated that the various steps described herein can be modified as necessary in the process of forming the plurality of sealed packages. Additionally, it should also be appreciated that in certain applications the order of the steps can be modified, certain steps can be omitted, and/or additional steps can be added without limiting the intended scope and breadth of the present invention.

Initially, in step 301, a first assembly member, e.g. a base, is provided, with the first assembly member defining a plurality of package cavities. The first assembly member has a base melting point. In step 303, a plurality of devices, e.g., integrated circuits or chips, are provided, with one or more devices being positioned in each package cavity.

In step 305, a plurality of seal members, e.g., formed from a solder or other braze material, are positioned spaced apart from and/or adjacent to one another along a first member surface, e.g., a base surface, of the first assembly member. The seal members are provided in preflow form. During such step, one or more seal members can be positioned to substantially encircle a cavity opening of each of the package cavities. The plurality of seal members can be said to have a first thickness, i.e. a seal thickness, which is the distance that the seal members extend away from the first member surface. Additionally, the seal members have a seal melting point that is lower than the base melting point.

In step 307, a plurality of spacers, e.g., also formed from a solder or other braze material, are positioned spaced apart from one another along the first member surface. The spacers are also provided in preflow form. The plurality of spacers can be said to have a second thickness, i.e. a spacer thickness, which is the distance that the spacers extend away from the first member surface. The second thickness is greater than the first thickness. Additionally, the spacers have a spacer melting point that is lower than the base melting point. The spacer melting point can be substantially similar to the seal melting point.

In step 309, a second assembly member, e.g., a lid, is positioned on top of the spacers with a second member surface, e.g., a lid surface, of the second assembly member in contact with the spacers. Due to the greater thickness of the spacers relative to the seal members, the lid surface is maintained spaced apart a fluid gap from the seal members. The second assembly member has a lid melting point that is greater than the seal melting point and the spacer melting point. In certain embodiments, the lid melting point is approximately equal to the base melting point.

In step 311, a controlled environment is created around the first assembly member and the second assembly member via a vacuum chamber. The vacuum chamber can be evacuated to a desired vacuum pressure level. Due to the fluid gap between the lid surface and the seal members, each of the cavities will also be evacuated to the same desired vacuum pressure level within the vacuum chamber.

In step 313, the assembly members, the seal members and the spacers are then heated to a desired temperature that is greater than or equal to the seal melting point and the spacer melting point, but is less than the base melting point and the lid melting point. Thus, the seal members and the spacers will melt down to a common thickness, and the seal members will form a seal ring around the cavity opening of each of the package cavities. Accordingly, the method will conclude with the forming of a plurality of hermetically sealed packages.

In some embodiments, the sealed packages can be subsequently separated from one another by cutting between adjacent sealed packages. For example, in certain embodiments, the sealed packages can be arranged in a number of rows and columns, and the sealed packages can be separated by cutting between the rows and/or between the columns of sealed packages.

It is understood that although a number of different embodiments of the package assembly 10 have been illustrated and described herein, one or more features of any one embodiment can be combined with one or more features of one or more of the other embodiments, provided that such combination satisfies the intent of the present invention.

While a number of exemplary aspects and embodiments of a package assembly 10 have been discussed above, those of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

What is claimed is:

1. A method of forming a plurality of sealed packages, the method comprising:
providing a base including a base surface;
providing a lid including a lid surface;
positioning a plurality of seal members along the base surface, the plurality of seal members being spaced apart from one another, the seal members being formed from a seal material including a fusible metal alloy;
positioning the lid on the base with a plurality of spaced apart spacers positioned and extending between the base surface and the lid surface, the spacers maintaining the lid surface spaced apart from the seal members by a fluid gap, the spacers being made from a spacer material including a fusible metal alloy;
creating a controlled environment around the base and the lid; and
heating to melt the spacers and the seal material so that the seal members form a plurality of seal rings between the base surface and the lid surface.

2. The method of claim 1 wherein positioning the plurality of seal members includes the seal members having a seal melting point, wherein positioning the lid includes the spacers having a spacer melting point, and wherein heating includes heating the base and the lid to at least the seal melting point and the spacer melting point to melt the spacers and the seal material so that the seal members form a plurality of seal rings between the base surface and the lid surface.

3. The method of claim 2 wherein providing the base includes the base having a base melting point, wherein providing the lid includes the lid having a lid melting point, wherein the base melting point and the lid melting point are both greater than the seal melting point and the spacer melting point, and wherein heating includes heating the base and the lid to below the base melting point and the lid melting point.

4. The method of claim 1 wherein the seal members have a seal thickness that extends away from the base surface, wherein the spacers have a spacer thickness that extends away from the base surface, and wherein the spacer thickness is greater than the seal thickness.

5. The method of claim 1 wherein providing the base includes the base defining a plurality of spaced apart package cavities, each package cavity including a cavity opening that is formed at the base surface, and wherein heating includes the seal members forming a plurality of seal rings between the base surface and the lid surface, with each seal ring encircling one of the cavity openings.

6. The method of claim 5 further comprising positioning a plurality of devices between the base surface and the lid surface prior to positioning the lid on the base such that one of the plurality of devices is positioned within each package cavity.

7. The method of claim 1 wherein creating includes positioning the base and the lid within a chamber and adjusting a chamber pressure within the chamber.

8. The method of claim 7 wherein adjusting includes evacuating gases from within the chamber.

9. The method of claim 7 wherein heating includes forming a sealed package within each seal ring between the base and the lid, and wherein each sealed package has a package pressure that is substantially identical to the chamber pressure.

10. The method of claim 1 wherein heating includes forming a sealed package within each seal ring between the base and the lid, and wherein each sealed package has a substantially identical package pressure.

11. A method of forming a plurality of sealed package, the method comprising:
providing a base including a base surface, the base having a base melting point;
providing a lid including a lid surface, the lid having a lid melting point;
positioning a plurality of seal members along the base surface, the plurality of seal members being spaced apart from one another, the seal members being formed from a seal material having a seal melting point that is below the base melting point and the lid melting point;
positioning the lid on the base with a plurality of spaced apart spacers positioned and extending between the base surface and the lid surface, the spacers maintaining the lid surface spaced apart from the base surface and the seal members, the spacers being made from a spacer material having a spacer melting point that is below the base melting point and the lid melting point;
creating a controlled environment around the base and the lid; and
heating to at least the seal melting point and the spacer melting point, but below the base melting point and the lid melting point to melt the spacers and the seal material so that the seal members form a plurality of seal rings between the base surface and the lid surface.

12. The method of claim 11 wherein positioning the plurality of seal members includes the seal members being formed from a fusible metal alloy, and wherein positioning the lid includes the spacers being formed from a fusible metal alloy.

13. The method of claim 11 wherein positioning the plurality of seal members includes the seal members having a seal thickness that extends away from the base surface, wherein positioning the lid includes the spacers having a spacer thickness that extends away from the base surface, and wherein the spacer thickness is greater than the seal thickness.

14. The method of claim 11 wherein providing the base includes the base defining a plurality of spaced apart package cavities, each package cavity including a cavity opening that is formed at the base surface, and wherein heating includes the seal members forming a plurality of seal rings between the base surface and the lid surface, with each seal ring encircling one of the cavity openings.

15. The method of claim 14 further comprising positioning a plurality of devices between the base surface and the lid surface prior to positioning the lid on the base such that one of the plurality of devices is positioned within each package cavity.

16. The method of claim 11 wherein creating includes positioning the base and the lid within a chamber and adjusting a chamber pressure within the chamber.

17. The method of claim 16 wherein adjusting includes evacuating gases from within the chamber.

18. The method of claim 16 wherein heating includes forming a sealed package within each seal ring between the base and the lid, and wherein each sealed package has a package pressure that is substantially identical to the chamber pressure.

19. The method of claim 11 wherein heating includes forming a sealed package within each seal ring between the base and the lid, and wherein each sealed package has a substantially identical package pressure.

20. A method of forming a plurality of sealed package, the method comprising:
providing a base including a base surface, the base having a base melting point, the base defining a plurality of spaced apart package cavities, each package cavity including a cavity opening that is formed at the base surface;
positioning one of a plurality of devices within each package cavity;
providing a lid including a lid surface, the lid having a lid melting point;
positioning a plurality of seal members along the base surface, the plurality of seal members being spaced apart from one another, the seal members being formed from a seal material including a fusible metal alloy, the seal members having a seal melting point that is below the base melting point and the lid melting point;
positioning the lid on the base with a plurality of spaced apart spacers positioned and extending between the base surface and the lid surface, the spacers maintaining the lid surface spaced apart from the seal members by a fluid gap, the spacers being made from a spacer material including a fusible metal alloy, the spacers having a spacer melting point that is below the base melting point and the lid melting point;
creating a controlled environment around the base and the lid by positioning the base in the lid within a chamber and adjusting a chamber pressure within the chamber; and
heating to at least the seal melting point and the spacer melting point, but below the base melting point and the lid melting point to melt the spacers and the seal material so that the seal members form a plurality of seal rings between the base surface and the lid surface, with each seal ring encircling one of the cavity openings to form a sealed package, wherein each sealed package has a package pressure that is substantially identical to the chamber pressure.
